(19) United States
(12) Patent Application Publication
(10) Pub. No.: US 2026/0150658 A1
(43) Pub. Date: May 28, 2026

(54) INTERCONNECT STRUCTURE WITH AN AIRGAP SURROUNDING BOTH A METAL LINE AND A VIA

(71) Applicant: INTERNATIONAL BUSINESS MACHINES CORPORATION, ARMONK, NY (US)

(72) Inventors: Ashim Dutta, Clifton Park, NY (US); Chih-Chao Yang, Glenmont, NY (US); Nilanka W. Sirikkathuge, Guilderland, NY (US); Kamal Rudra, Albany, NY (US)

(21) Appl. No.: 18/962,287

(22) Filed: Nov. 27, 2024

(51) Int. Cl. H10W 20/46; H10W 20/00; H10W 20/41; H10W 20/42; H10W 20/48

(52) U.S. Cl. CPC H10W 20/46; H10W 20/072; H10W 20/075; H10W 20/42; H10W 20/435; H10W 20/48; H10W 20/085

(57) ABSTRACT

An interconnect structure a Mx level that includes a Mx metal line. A Mx+1 level located on top of the Mx level. The Mx+1 level includes an Mx+1 metal line and Mx+1 metal via, and the Mx+1 metal via is connected to the Mx metal line. An airgap located within the Mx+1 level and the airgap is located around the Mx+1 metal line and the Mx+1 metal via.

### BACKGROUND

The present invention generally relates to the field of microelectronics, and more particularly to forming an airgap around a metal line and via.

Interconnects are used to make connections to the devices that the interconnect are mounted on. The spacing of the components is decreasing as the devices are scaled down which is causing the spacing within the interconnects to decrease. The decreased spacing in the interconnects is causing the rise in parasitic defects.

### BRIEF SUMMARY

Additional aspects and/or advantages will be set forth in part in the description which follows and, in part, will be apparent from the description, or may be learned by practice of the invention.

An interconnect structure a Mx level that includes a Mx metal line. A Mx+1 level located on top of the Mx level. The Mx+1 level includes an Mx+1 metal line and Mx+1 metal via, and the Mx+1 metal via is connected to the Mx metal line. An airgap located within the Mx+1 level and the airgap is located around the Mx+1 metal line and the Mx+1 metal via.

An interconnect structure including a Mx level that includes a Mx metal line. A Mx+1 level located on top of the Mx level. The Mx+1 level includes an Mx+1 metal line and Mx+1 metal via. The Mx+1 metal via is connected to the Mx metal line. A Mx+1 dielectric liner located around sections of the Mx+1 metal line and the Mx+1 metal via. An airgap located within the Mx+1 level and the airgap is located around the Mx+1 metal line and the Mx+1 metal via.

A method for forming an interconnect that includes the steps of forming a Mx level that includes a Mx metal line. Forming a Mx+1 level located on top of the Mx level. Forming a Mx+1 dielectric liner within the Mx+1 level. Forming an Mx+1 metal line and Mx+1 metal via within the Mx+1 level. The Mx+1 metal via is connected to the Mx metal line. The Mx+1 dielectric liner is located around sections of the Mx+1 metal line and the Mx+1 metal via. Forming an airgap located within the Mx+1 level and the airgap is located around the Mx+1 metal line and the Mx+1 metal via.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross-section view of an interconnect after the initial formation of the Mx+1 level, in accordance with an embodiment of the present invention.

FIG. 2 illustrates a cross-section view of an interconnect after the formation and patterning of a lithography layer, in accordance with an embodiment of the present invention.

FIG. 3 illustrates a cross-section view of an interconnect after the formation of an initial Mx+1 trench, in accordance with an embodiment of the present invention.

FIG. 4 illustrates a cross-section view of an interconnect after the formation of a second lithography layer, a cap layer, and a third lithography layer, in accordance with an embodiment of the present invention.

FIG. 5 illustrates a cross-section view of an interconnect after the formation of an initial Mx+1 via trench, in accordance with an embodiment of the present invention.

FIG. 6 illustrates a cross-section view of an interconnect after the removal of the second lithography layer, in accordance with an embodiment of the present invention.

FIG. 7 illustrates a cross-section view of an interconnect after formation of a temporary layer, in accordance with an embodiment of the present invention.

FIG. 8 illustrates a cross-section view of an interconnect after formation of a sacrificial layer, in accordance with an embodiment of the present invention.

FIG. 9 illustrates a cross-section view of an interconnect after removal of the temporary layer, in accordance with an embodiment of the present invention.

FIG. 10 illustrates a cross-section view of an interconnect after formation of the Mx+1 dielectric liner, in accordance with an embodiment of the present invention.

FIG. 11 illustrates a cross-section view of an interconnect after etching of the Mx+1 dielectric liner and the first etch stop layer, in accordance with an embodiment of the present invention.

FIG. 12 illustrates a cross-section view of an interconnect after formation of the Mx+1 metal liner, Mx+1 metal line, and Mx+1 metal via, in accordance with an embodiment of the present invention.

FIG. 13 illustrates a cross-section view of an interconnect after formation of the airgap, in accordance with an embodiment of the present invention.

FIG. 14 illustrates a cross-section view of an interconnect after formation of the cap, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art of affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. Interconnects are used to make connections to the devices that the interconnect are mounted on. The spacing or distance between components located within the device is decreasing as the devices are scaled down. The reduced spacing/distance within the devices is causing the spacing or distance between elements of the interconnect to be reduced. The decreased spacing in the interconnects is causing the rise in parasitic defects. The parasitic defects, such as parasitic capacitance that are formed by two metal components that are located relatively close to each other and have a current running through the metal components. The present invention is directed towards reducing the parasitic capacitance between the metal components in the interconnect. The present invention is able to reduce parasitic capacitance by forming an airgap around at least one of the metal components. The airgap is located along the vertical, horizontal, and around the via extending off the metal component.

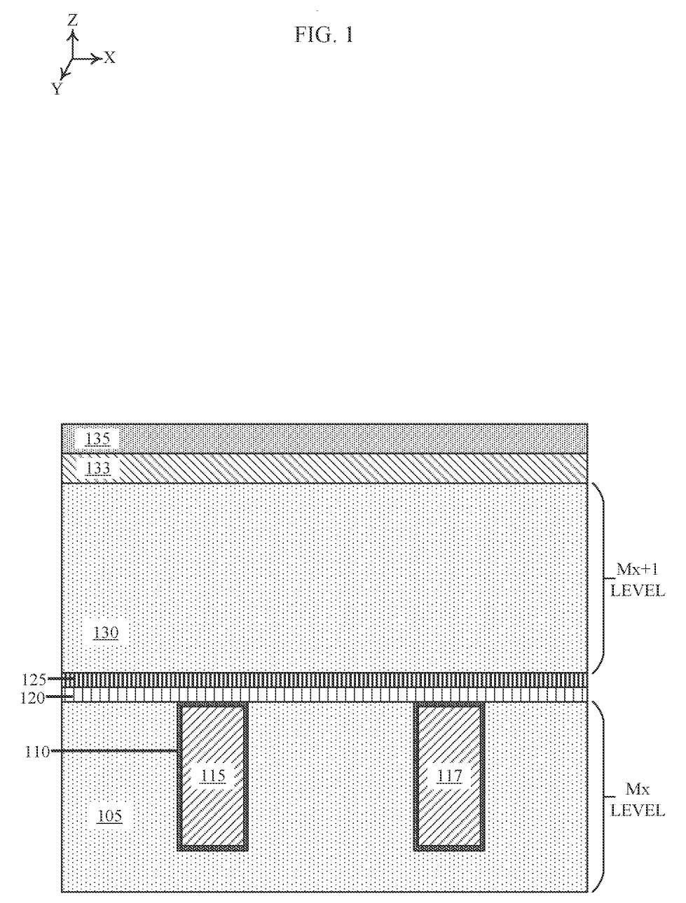

FIG. 1 illustrates a cross-section of an interconnect after the initial formation of the Mx+1 level, in accordance with the embodiment of the present invention. The illustrated cross-section is perpendicular to cross multiple metal lines located in the Mx level and the Mx+1 level. The Mx level includes a Mx dielectric layer 105, a first Mx metal line 115, a second Mx metal line 117, and a Mx metal liner 110. The Mx metal liner 110 surrounds the first Mx metal line 115 and surrounds the second Mx metal line 117. A first etch stop layer 120 is located on top of the Mx level. The first etch stop layer 120 can be comprised of, for example, AlOₓ, AlN, or a similar material. A second etch stop layer 125 is located on top of the first etch stop layer 120. The second etch stop layer 125 can be comprised of, for example, SiCO or another suitable material. The first etch stop layer 120 and the second etch stop layer 125 are comprised of different materials. The Mx+1 level is located on top of the second etch stop layer 125. The Mx+1 level includes a Mx+1 dielectric layer 130. A Mx+1 first layer 133 is formed on top of the Mx+1 dielectric layer 130 and a Mx+1 second layer 135 is formed on top of the Mx+1 first layer 133.

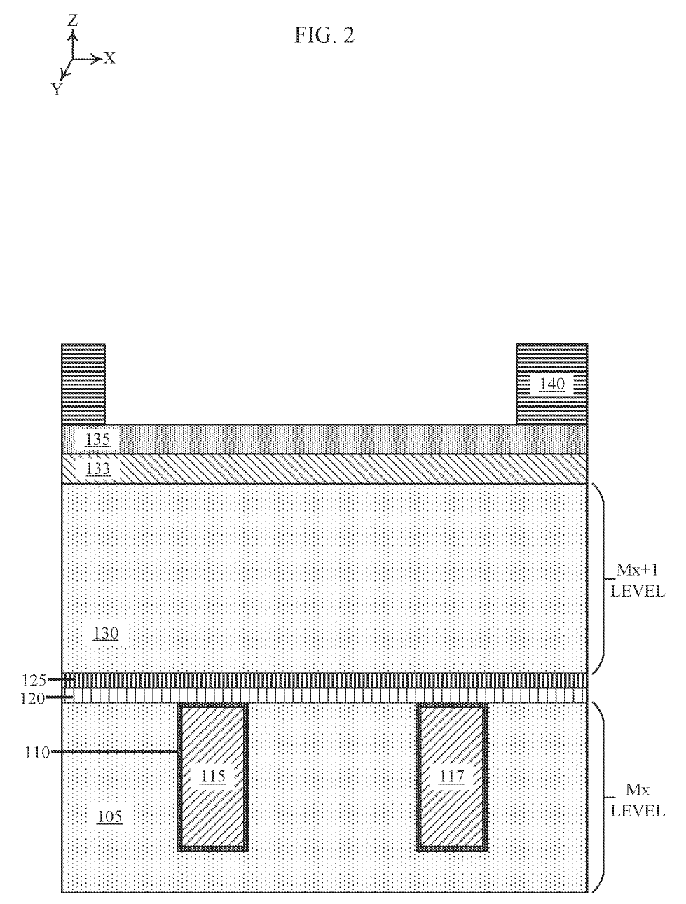

FIG. 2 illustrates the processing stage after the formation and patterning of a first lithography layer 140. First lithography layer 140 is formed on top of the Mx+1 second layer 135 and the first lithography layer 140 is patterned. The patterning of the first lithography layer 140 will determine the location where different components will be formed within the Mx+1 level.

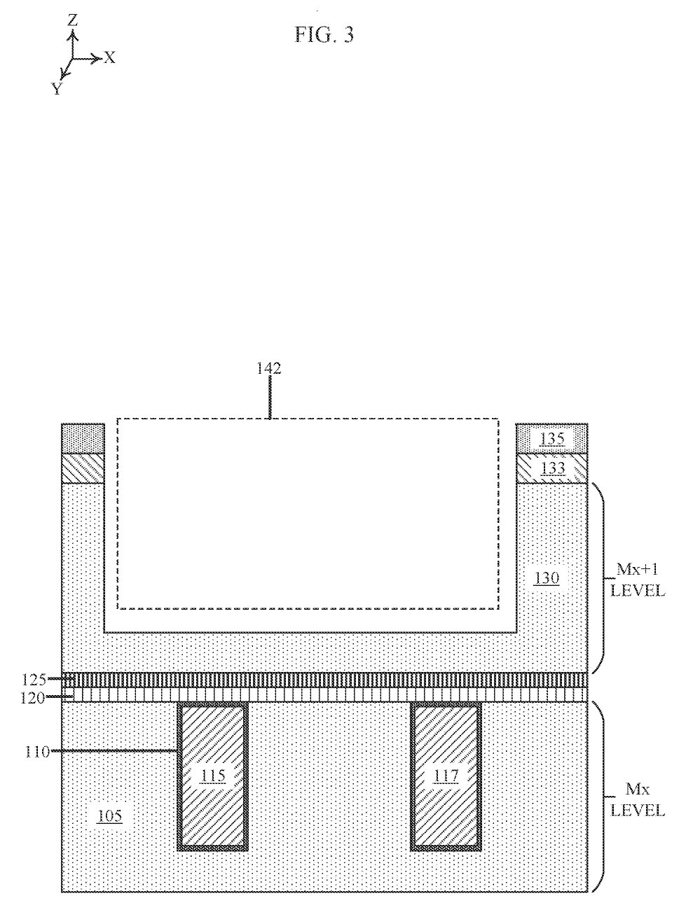

FIG. 3 illustrates the processing stage after the formation of the initial Mx+1 trench 142. The second Mx+1 layer 135, the first Mx+1 layer 133, and the Mx+1 dielectric layer 130 are etched to form the initial Mx+1 trench 142. The first lithography layer 140 is removed. The initial Mx+1 trench 142 extends downwards into the Mx+1 dielectric layer 130 but the initial Mx+1 trench 142 does not extend downwards to the second etch stop layer 125. The initial Mx+1 trench 142 can be perpendicular to the first Mx metal line 115 and the second Mx metal line 117 such that the width of the initial Mx+1 trench 142 is wider than the spacing of the first Mx metal line 115 and the second Mx metal line 117. Alternatively, the initial Mx+1 trench 142 could be formed parallel to one of the first or second Mx metal lines 115, 117.

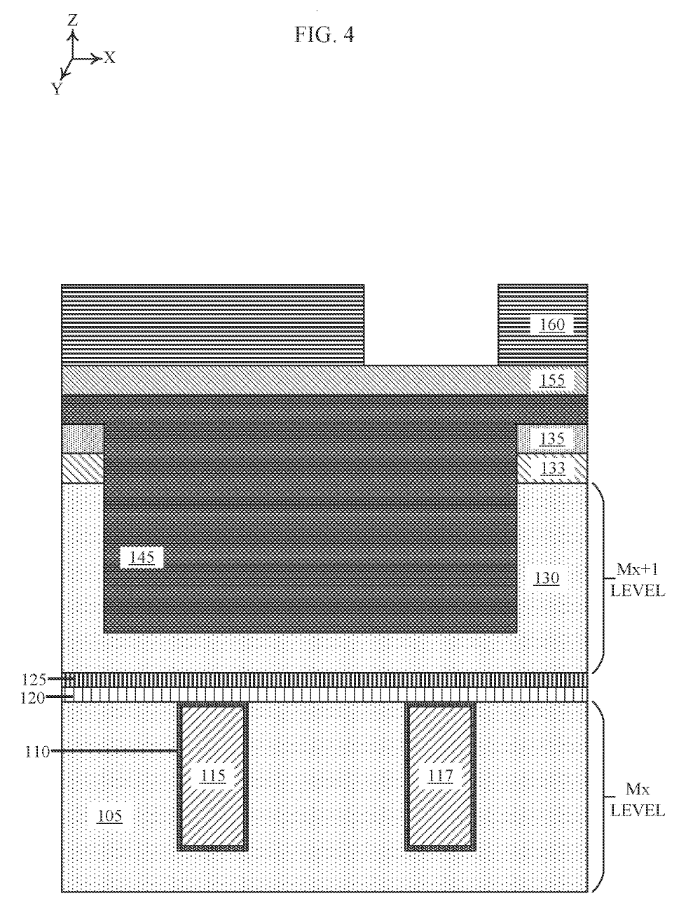

FIG. 4 illustrates the processing stage after the formation of a second lithography layer 145, a cap layer 155, and a third lithography layer 160. A second lithography layer 145 is formed within the initial Mx+1 trench 142 and on top of the remaining portions of the Mx+1 second layer 135. A cap layer 155 is formed on top of the second lithography layer 145. A third lithography layer 160 is formed on top of the cap layer 155. The third lithography layer 160 is patterned to determine the location where via(s) will be formed in the Mx+1 level. The via(s) will be aligned with one or more of the first and/or second Mx metal lines 115, 117.

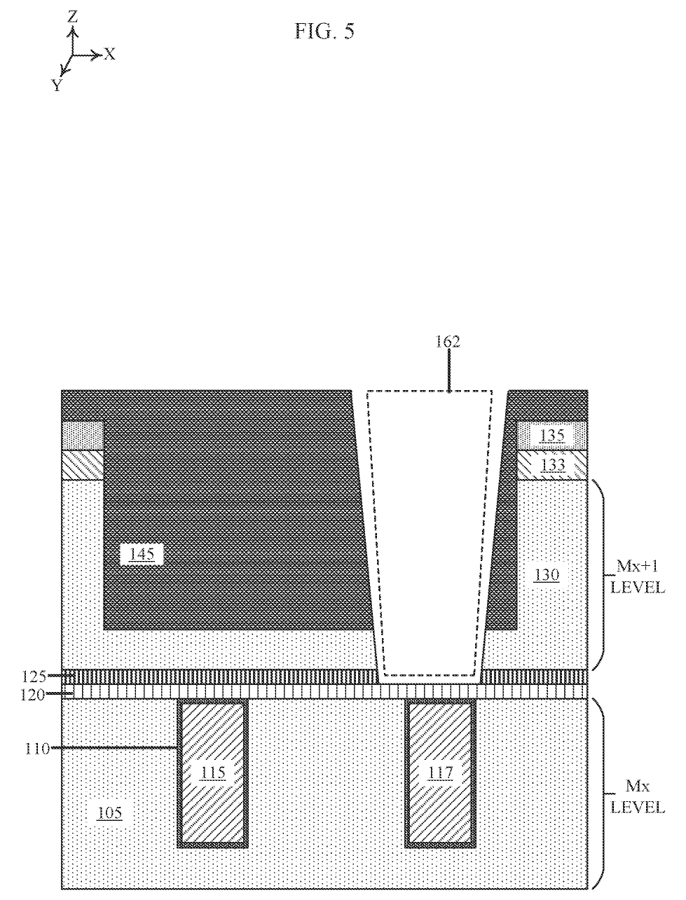

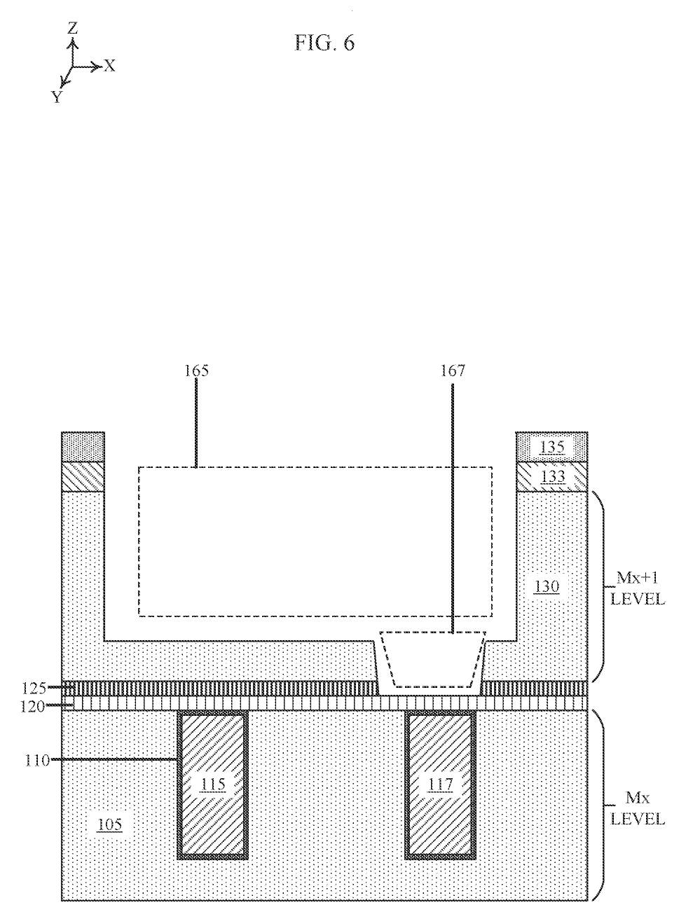

FIG. 5 illustrates the processing stage after the formation of an initial Mx+1 via trench 162. The cap layer 155, the second lithography layer 145, the Mx+1 dielectric layer 130, and the second etch stop layer 125 are etched to form the initial Mx+1 via trench 162. The third lithography layer 160 and the cap layer 155 are removed. The initial Mx+1 via trench 162 is vertically aligned with the first or second Mx metal lines 115, 117. FIG. 5 illustrates that the initial Mx+1 via trench 162 is aligned with the second Mx metal line 117, but this is only for example purposes only. FIG. 6 illustrates the processing stage after the removal of the second lithography layer 145. The second lithography layer 145 is removed to expose the Mx+1 trench 165 that includes the Mx+1 via trench 167.

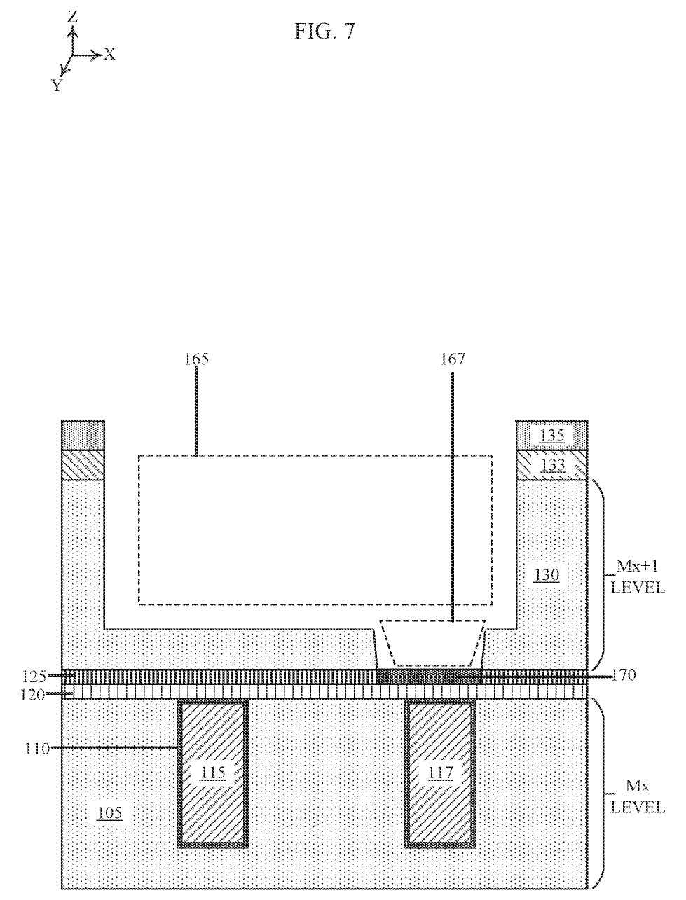

FIG. 7 illustrates the processing stage after the formation of temporary layer 170. The temporary layer 170 is formed by, for example, a self-assembly-monolayer (SAM) process at the bottom of Mx+1 via trench 167. Specifically, the temporary layer 170 is formed on top of the first etch stop layer 120 that was exposed by the Mx+1 via trench 167. The temporary layer 170 can have a thickness in the range of about 1 to 10 nanometers, preferably in the range of about 2 to 4 nanometers.

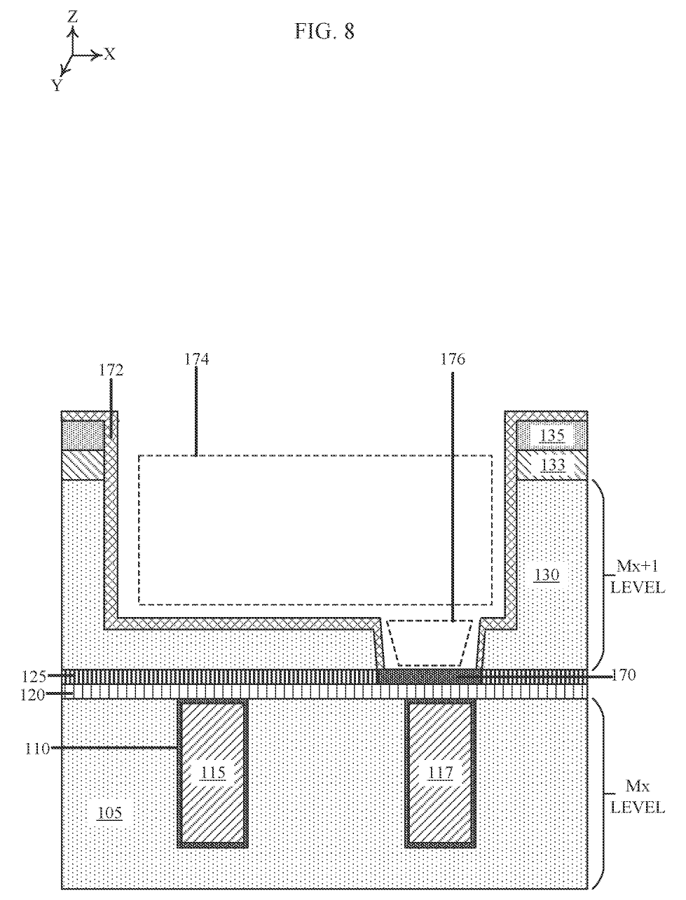

FIG. 8 illustrates the processing stage after the formation of sacrificial layer 172. The sacrificial layer 172 is formed on the exposed surfaces on top of the Mx+1 second layer 135, along the surfaces of the Mx+1 trench 165 and the side surfaces of the Mx+1 via trench 167. Mx+1 trench 165 will now be referred to as the initial Mx+1 lined trench 174 and the Mx+1 via trench 167 will now be referred to as the initial Mx+1 lined via trench 176. The sacrificial layer 172 can be comprised of a dielectric material, for example, SiN, SiOₓ, SiC, HfOₓ, LaOₓ, another suitable dielectric material, or a different material. The temporary layer 170 prevents the sacrificial layer 172 from being formed on the bottom surface of the initial Mx+1 lined via trench 176. The sacrificial layer 172 is located along the vertical sidewalls and the bottom boundary of the initial Mx+1 lined trench 174. The sacrificial layer 172 is also located on the sidewalls of the initial Mx+1 lined via trench 176.

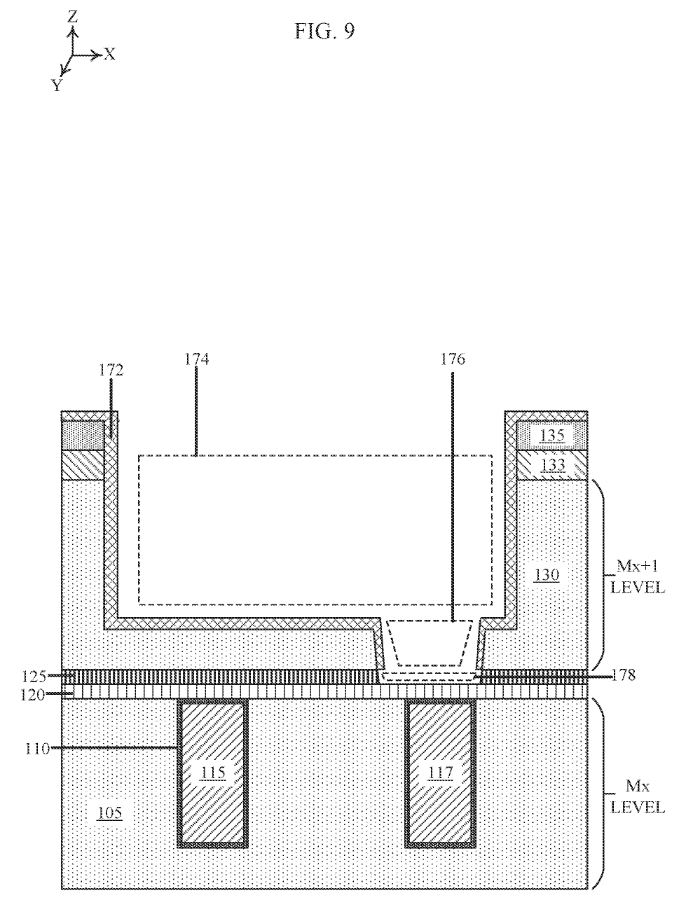

FIG. 9 illustrates the processing stage after the removal of the temporary layer 170. The temporary layer 170 is removed. The removal of the temporary layer 170 to create an empty space located above the exposed first etch stop layer 120. The empty space is emphasized by dashed box 178. Empty space 178 extends under portions of the sacrificial layer 172 located along the sidewalls of the initial Mx+1 lined trench 176.

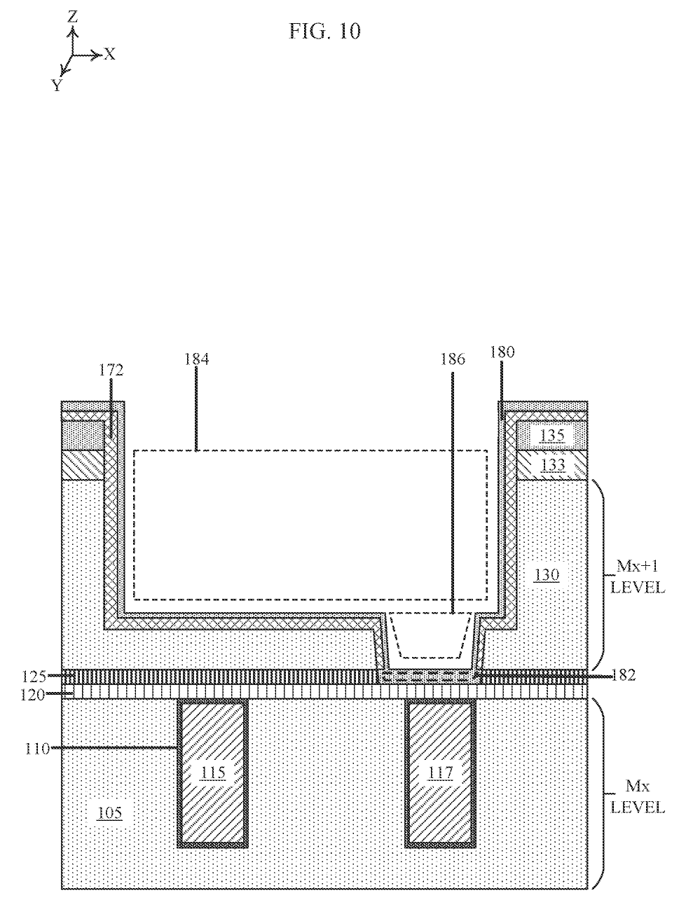

FIG. 10 illustrates the processing stage after the formation of the Mx+1 dielectric liner 180. The Mx+1 dielectric liner 180 is formed on top of the sacrificial layer 172. Initial Mx+1 line trench 174 will now be referred to as the Mx+1 double lined trench 184 and the initial Mx+1 lined via trench 174 will now be referred to as the Mx+1 double lined via trench 186. The Mx+1 dielectric liner 180 is located on top of the sacrificial layer 172 located on the vertical sidewalls and the bottom wall of the Mx+1 doubled lined trench 184. Mx+1 dielectric liner 180 is located on the sacrificial layer 172 along the sidewalls of the Mx+1 doubled lined trench 186. Furthermore, the Mx+1 dielectric liner 180 is formed in the empty space 178 as emphasized by dashed box 182. The Mx+1 dielectric liner 180 extends under the sacrificial layers 172 located on the sidewalls of the Mx+1 doubled lined trench 186.

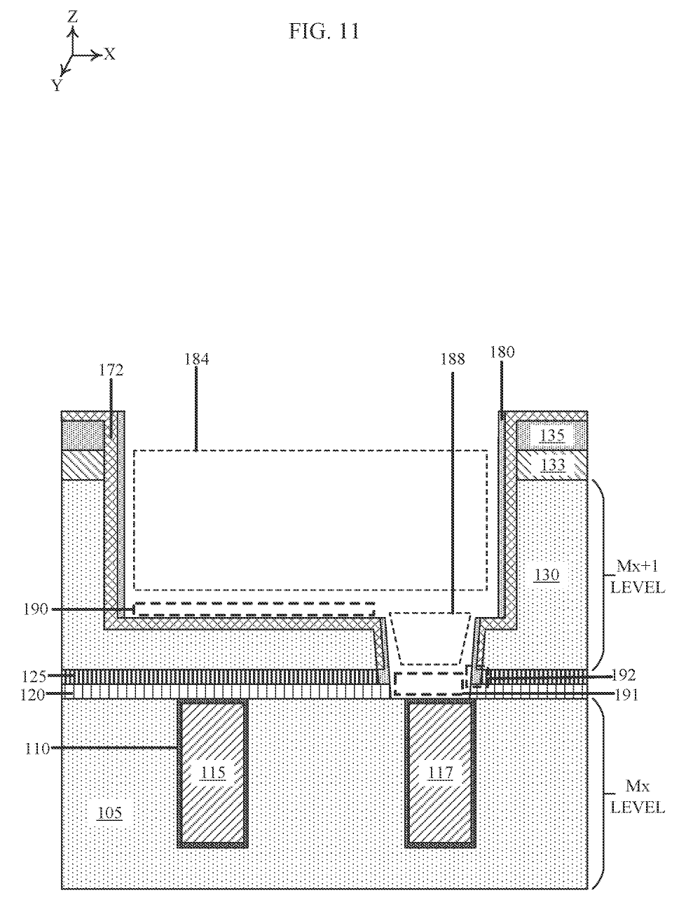

FIG. 11 illustrates the processing stage after etching of the Mx+1 dielectric liner 180 and the first etch stop layer 120. The Mx+1 dielectric layer 180 is etched to remove the horizontal sections of the layer. For example, dashed box 190 emphasizes one of the removed horizontal sections of the Mx+1 dielectric layer 180 which exposes a horizontal section of the sacrificial layer 172. A portion of the horizontal section of the Mx+1 dielectric layer 190 located in the Mx+1 doubled lined via trench 186 is removed and a portion of the first etch stop layer 120 is removed. The removal of these layers extends the Mx+1 doubled lined via trench 186 to the underlying Mx metal layer (e.g., the second Mx metal line 117). Hereinafter, the Mx+1 doubled lined via trench 186 will be referred to as the extended Mx+1 doubled lined via trench 188. A surface of the Mx metal liner 110 located around the second Mx metal line 117 is exposed, as emphasized by dashed box 191. Dashed box 192 emphasized the portion of the Mx+1 dielectric layer 180 that will remain beneath the sacrificial layer 172 after the formation of the extended Mx+1 doubled lined via trench 188. This portion as emphasized by dashed box 192 helps to seal off the bottom of the sacrificial layer 172 from the open space of the extended Mx+1 double lined via trench 188.

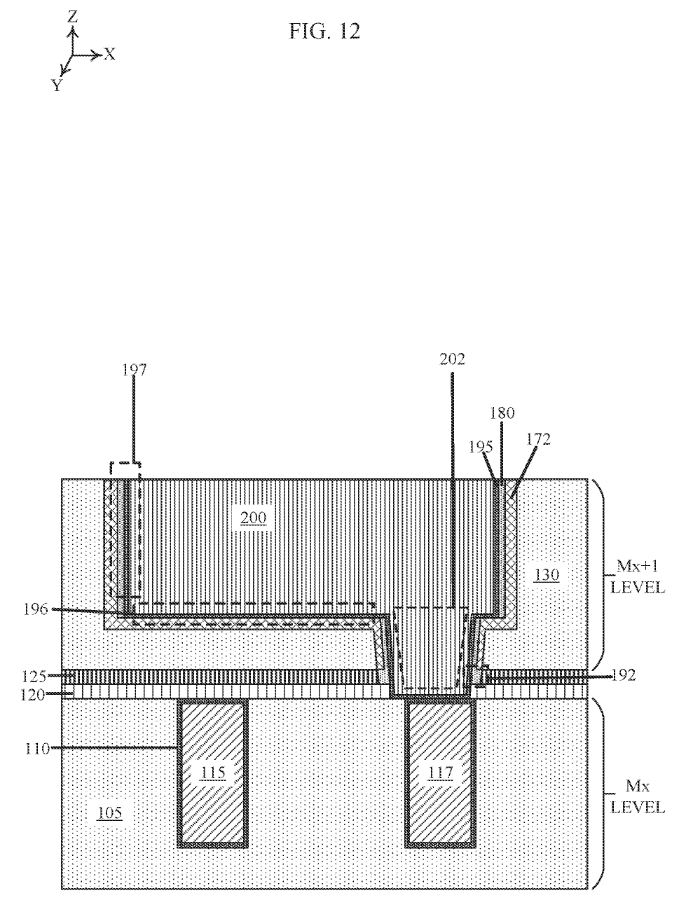

FIG. 12 illustrates the processing stage after the formation of the Mx+1 metal liner 195, the Mx+1 metal line 200, and the Mx+1 metal via 202. The Mx+1 metal liner 195 is formed on the exposed surfaces of the Mx+1 dielectric layer 180, the sacrificial layer 172, the first etch stop layer 120, and the Mx metal liner 110. Dashed box 196 emphasizes the horizontal region where the Mx+1 metal liner 195 is in direct contact with a horizontal section of the sacrificial layer 172. Dashed box 197 emphasizes a vertical section where the Mx+1 dielectric layer 180 is located between the sacrificial layer 172 and the Mx+1 metal liner 195. The Mx+1 metal liner 195 extends along the boundaries of the extended Mx+1 doubled line via trench 188, such that the Mx+1 metal liner 195 is in contact with the first etch stop 120, the Mx metal liner 110, and the Mx+1 dielectric liner 180 located within the extended Mx+1 doubled lined via trench 188. A metallization process fills the Mx+1 double lined trench 184 and the extended Mx+1 doubled lined via trench 188 with a conductive metal to form the Mx+1 metal line 200 and the Mx+1 metal via 202. Excess metal material is removed by a planarization process, for example, chemical mechanical planarization (CMP) which causes the remaining portions of the Mx+1 first layer 133, and the Mx+1 second layer 135 to be removed.

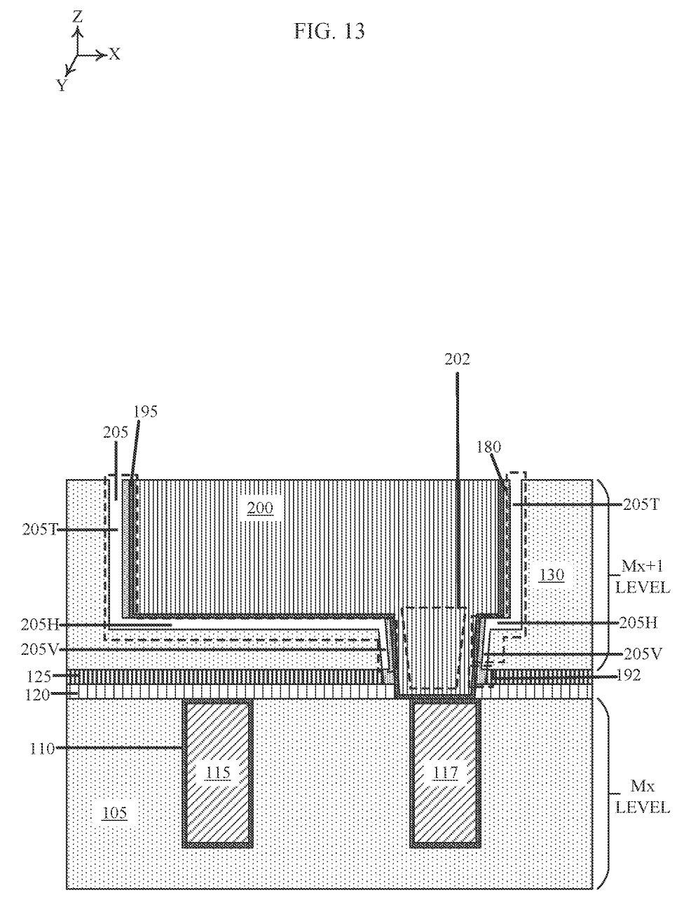

FIG. 13 illustrates the processing stage after the formation of the airgap 205. The sacrificial layer 172 is selectively removed while the Mx+1 dielectric liner 180 is not removed. The sacrificial layer 172 and the Mx+1 dielectric liner 180 are comprised of different materials to allow for the selective removal of the sacrificial layer 172 by, for example, an isotropic etch process. The removal of the sacrificial layer 172 causes the formation of airgap 205. Airgap 205 extends around the Mx+1 metal line 200 and the Mx+1 metal via 202. Airgap 205 includes vertical sections 205T, horizontal sections 205H, and via sections 205V. Vertical sections 205T of the airgap 205 are located between the Mx+1 dielectric liner 180 and the Mx+1 dielectric layer 130. Mx+1 dielectric liner 180 is located between the Mx+1 metal liner 195 and the vertical sections 205T of airgap 205. The horizontal sections 205H of the airgap 205 are located between the Mx+1 metal liner 195 and the Mx+1 dielectric layer 130. This means that the Mx+1 dielectric liner 180 forms one of the vertical boundaries of the vertical sections 205T of the airgap 205 and the Mx+1 metal liner 195 forms one of the boundaries of the horizontal sections 205H of the airgap 205. The via sections 205V of the airgap 205 are located between the Mx+1 dielectric liner 180 and the Mx+1 dielectric layer 130 located around the Mx+1 metal via 202. The overlap sections of the Mx+1 dielectric liner 180 as emphasized by dashed box 192 prevents the via sections 205V of the airgap 205 from reaching the first etch stop layer 120. The Mx+1 metal via 202 extends lower than via section 205V of the airgap 205.

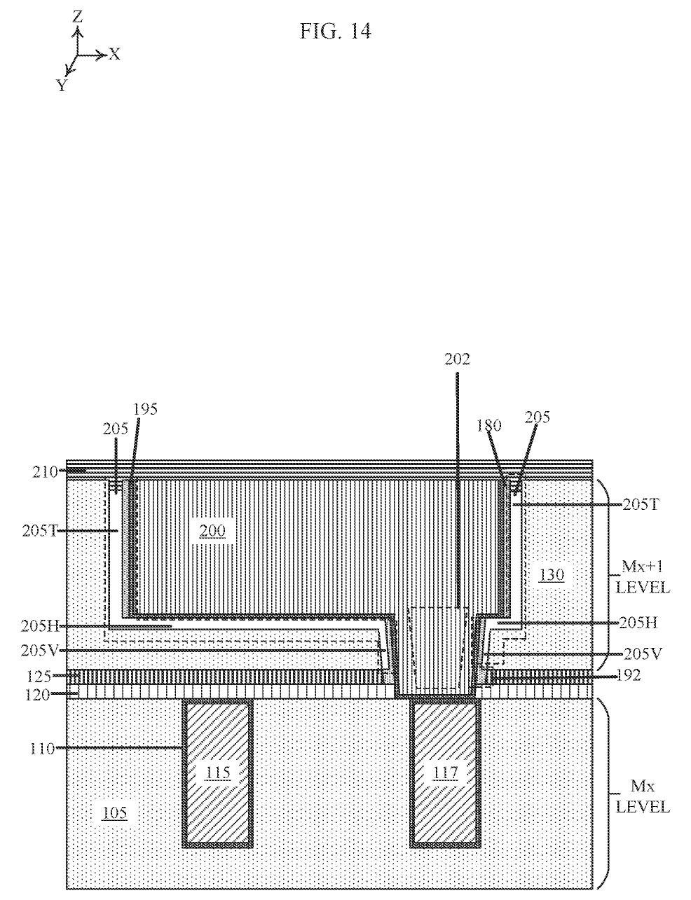

FIG. 14 illustrates the processing stage after the formation of cap 210. Cap 210 is formed on top of the Mx+1 level, such that the cap 210 is formed on top of the Mx+1 metal line 200, Mx+1 metal liner 195, the Mx+1 dielectric liner 180, the Mx+1 dielectric layer 130, and airgap 205. Cap 210 seals airgap 205, such that the cap 210 includes small protrusion that extended into vertical sections 205T of the airgap 205. The airgap 205 allows for a reduction of the parasitic capacitance between the Mx+1 metal line 200, the Mx+1 metal via 202 and any adjacent metal components (such as the first and second Mx metal lines 115, 117). The thickness of the airgap 205 determines how much the parasitic capacitance is reduced.

An interconnect structure a Mx level that includes a Mx metal line 115, 117. A Mx+1 level located on top of the Mx level. The Mx+1 level includes an Mx+1 metal line 195, 200 and Mx+1 metal via 195, 202, and the Mx+1 metal via 195, 202 is connected to the Mx metal line 117. An airgap 205 located within the Mx+1 level and the airgap 205 is located around the Mx+1 metal line 195, 200 and the Mx+1 metal via 195, 202.

The airgap 205 includes vertical sections 205T, horizontal sections 205H, and via sections 205V.

The Mx+1 metal line 195, 200 includes a Mx+1 metal liner 195 and a Mx+1 metal fill 200. The Mx+1 metal liner 195 forms a boundary of a section of the airgap 205, 205H. The airgap 205 includes a vertical section 205T, a horizontal section 205H, and a via section 205V. The Mx+1 metal liner 195 forms a boundary for the horizontal section 205H of the airgap 205. The Mx+1 metal via 195, 202 extends lower than the via sections 205V of the airgap 205.

An interconnect structure including a Mx level that includes a Mx metal line 115, 117. A Mx+1 level located on top of the Mx level. The Mx+1 level includes an Mx+1 metal line 195, 200 and Mx+1 metal via 195, 202. The Mx+1 metal via 195, 202 is connected to the Mx metal line 117. A Mx+1 dielectric liner 180 located around sections of the Mx+1 metal line 195, 200 and the Mx+1 metal via 195, 202. An airgap 205 located within the Mx+1 level and the airgap 205 is located around the Mx+1 metal line 195, 200 and the Mx+1 metal via 195, 202.

The airgap 205 includes vertical sections 205T, horizontal sections 205H, and via sections 205V.

The Mx+1 metal line 195, 200 includes a Mx+1 metal liner 195 and a Mx+1 metal fill 200. The Mx+1 metal liner 195 forms a boundary of a section of the airgap 205. The airgap 205 includes a vertical section 205T, a horizontal section 205H, and a via section 205V. The Mx+1 metal liner 195 forms a boundary for the horizontal section 205H of the airgap 205. The Mx+1 dielectric liner 180 includes a vertical section and a via section. The vertical sections of the Mx+1 dielectric liner 180 are located between the Mx+1 metal liner 195 and the vertical section 205T of the airgap 205. The via section of the Mx+1 dielectric liner 180 are located between the Mx+1 metal liner 195 and the via section 205V of the airgap 205. The Mx+1 metal via 195, 202 extends lower than the via sections 205V of the airgap 205.

A method for forming an interconnect that includes the steps of forming a Mx level that includes a Mx metal line 115, 117. Forming a Mx+1 level located on top of the Mx level. Forming a Mx+1 dielectric liner 180 within the Mx+1 level. Forming an Mx+1 metal line 195, 200 and Mx+1 metal via 195, 202 within the Mx+1 level. The Mx+1 metal via 195, 202 is connected to the Mx metal line 117. The Mx+1 dielectric liner 180 is located around sections of the Mx+1 metal line 195, 200 and the Mx+1 metal via 195, 202. Forming an airgap 205 located within the Mx+1 level and the airgap 205 is located around the Mx+1 metal line 195, 200 and the Mx+1 metal via 195, 202.

The Mx+1 metal line 195, 200 includes a Mx+1 metal liner 195 and a Mx+1 metal fill 200. The airgap 205 includes a vertical section 205T, a horizontal section 205H, and a via section 205V. The Mx+1 metal liner 195 forms a boundary for the horizontal section 205H of the airgap 205.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of one or more embodiments, the practical application or technical improvement over technologies found in the marketplace, or to enable others of ordinary skill in the art to understand the embodiments disclosed herein.

What is claimed is:

1. An interconnect structure comprising:
a Mx level that includes a Mx metal line;
a Mx+1 level located on top of the Mx level, wherein the Mx+1 level includes an Mx+1 metal line and Mx+1 metal via, where the Mx+1 metal via is connected to the Mx metal line; and
an airgap located within the Mx+1 level, wherein the airgap is located around the Mx+1 metal line and the Mx+1 metal via.

2. The interconnect of claim 1, wherein the airgap includes vertical sections, horizontal sections, and via sections.

3. The interconnect of claim 1, wherein the Mx+1 metal line includes a Mx+1 metal liner and a Mx+1 metal fill.

4. The interconnect of claim 3, wherein the Mx+1 metal liner forms a boundary of a section of the airgap.

5. The interconnect of claim 4, wherein the airgap includes a vertical section, a horizontal section, and a via section.

6. The interconnect of claim 5, wherein the Mx+1 metal liner forms a boundary for the horizontal section of the airgap.

7. The interconnect of claim 6, wherein the Mx+1 metal via extends lower than the via sections of the airgap.

8. An interconnect structure comprising:
a Mx level that includes a Mx metal line;
a Mx+1 level located on top of the Mx level, wherein the Mx+1 level includes an Mx+1 metal line and Mx+1 metal via, where the Mx+1 metal via is connected to the Mx metal line;
a Mx+1 dielectric liner located around sections of the Mx+1 metal line and the Mx+1 metal via; and
an airgap located within the Mx+1 level, wherein the airgap is located around the Mx+1 metal line and the Mx+1 metal via.

9. The interconnect of claim 8, wherein the airgap includes vertical sections, horizontal sections, and via sections.

10. The interconnect of claim 8, wherein the Mx+1 metal line includes a Mx+1 metal liner and a Mx+1 metal fill.

11. The interconnect of claim 10, wherein the Mx+1 metal liner forms a boundary of a section of the airgap.

12. The interconnect of claim 11, wherein the airgap includes a vertical section, a horizontal section, and a via section.

13. The interconnect of claim 12, wherein the Mx+1 metal liner forms a boundary for the horizontal section of the airgap.

14. The interconnect of claim 13, wherein the Mx+1 dielectric liner includes a vertical section and a via section.

15. The interconnect of claim 14, wherein the vertical sections of the Mx+1 dielectric liner are located between the Mx+1 metal liner and the vertical section of the airgap.

16. The interconnect of claim 15, wherein the via section of the Mx+1 dielectric liner are located between the Mx+1 metal liner and the via section of the airgap.

17. The interconnect of claim 6, wherein the Mx+1 metal via extends lower than the via sections of the airgap.

18. A method for forming an interconnect comprising:
forming a Mx level that includes a Mx metal line;
forming a Mx+1 level located on top of the Mx level,
forming a Mx+1 dielectric liner within the Mx+1 level
forming an Mx+1 metal line and Mx+1 metal via within the Mx+1 level, where the Mx+1 metal via is connected to the Mx metal line, wherein the Mx+1 dielectric liner is located around sections of the Mx+1 metal line and the Mx+1 metal via; and
forming an airgap located within the Mx+1 level, wherein the airgap is located around the Mx+1 metal line and the Mx+1 metal via.

19. The method of claim 18, wherein the Mx+1 metal line includes a Mx+1 metal liner and a Mx+1 metal fill.

20. The method of claim 19, wherein the airgap includes a vertical section, a horizontal section, and a via section, wherein the Mx+1 metal liner forms a boundary for the horizontal section of the airgap.
